(19) United States
(12) Patent Application Publication
(10) Pub. No.: US 2024/0421234 A1
(43) Pub. Date: Dec. 19, 2024

(54) SEMICONDUCTOR DEVICE AND METHOD OF MANUFACTURING THE SAME

(71) Applicant: Renesas Electronics Corporation, Tokyo (JP)

(72) Inventor: Fumitoshi TAKAHASHI, Tokyo (JP)

(21) Appl. No.: 18/646,495

(22) Filed: Apr. 25, 2024

(30) Foreign Application Priority Data
Jun. 14, 2023 (JP) 2023-097745

(51) Int. Cl. H01L 29/866; G05F 1/46; G05F 3/18; H01L 27/06; H01L 29/66

(52) U.S. Cl. CPC H01L 29/866; H01L 27/0647; H01L 29/66106; G05F 1/468; G05F 3/18

(57) ABSTRACT

In a semiconductor substrate, an n-type cathode region, an n-type well region, and a p-type anode region are formed. An impurity concentration of the cathode region is higher than an impurity concentration of the well region. In plan view, the anode region includes the cathode region, and the well region includes the anode region and the cathode region. A depth of the well region from an upper surface of the semiconductor substrate is greater than a depth of the anode region from the upper surface of the semiconductor substrate. A depth of the cathode region from the upper surface of the semiconductor substrate is greater than the respective depths of the anode region and the well region.

### CROSS-REFERENCE TO RELATED APPLICATIONS

The disclosure of Japanese Patent Application No. 2023-097745 filed on Jun. 14, 2023, including the specification, drawings and abstract is incorporated herein by reference in its entirety.

### BACKGROUND

The present disclosure relates to a semiconductor device and method of manufacturing the same, and more particularly, to a semiconductor device including a Zener diode and method of manufacturing the same.

The semiconductor device incorporates a protection circuit to protect the MISFET (Metal Insulator Semiconductor Field Effect Transistor) from surge voltages and the like.

There is a disclosed technique listed below.
[Patent Document 1] Japanese Unexamined Patent Application Publication No. 2013-183039

For example, Patent Document 1 discloses a semiconductor device including a MISFET and a protection circuit, and a Zener diode configuring this protection circuit.

### SUMMARY

A semiconductor device for driving a power device includes a DESAT detection circuit (saturated collector voltage detection circuit). The DESAT detection circuit needs to narrow the standard width of the DESAT detection voltage to prevent malfunction due to noise. Therefore, it is preferable that the variation in the absolute value of the generated voltage in the reference voltage generation part in the DESAT detection circuit is small, and the temperature characteristics of the reference voltage generation part are small.

For example, by configuring the reference voltage generation part with a BGR circuit (bandgap reference circuit), the standard width of the DESAT detection voltage can be narrowed. However, since there are many components that configure the BGR circuit, the area of the BGR circuit becomes large. Therefore, the application of the BGR circuit is not effective from the viewpoint of increasing the chip area.

In order to realize the reference voltage generation part in a small area, the inventors of the present application newly considered configuring the reference voltage generation part using a Zener diode and an emitter base diode connected in the forward direction. The reference voltage generation part using these diodes can reduce the area compared to the BGR circuit. The Zener diode requires a small variation in the breakdown voltage Vz and stable temperature characteristics.

The generated voltage of the reference voltage generation part is determined by the breakdown voltage Vz of the Zener diode and the forward voltage Vf of the emitter base diode. Therefore, if the breakdown voltage Vz varies, the generated voltage of the reference voltage generation part will also vary. Since the DESAT detection voltage is determined by the generated voltage of the reference voltage generation part, it is not possible to narrow the standard width of the DESAT detection voltage due to the variation in the breakdown voltage Vz. Also, since the breakdown voltage Vz affects the ratio of positive and negative temperature characteristics of the Zener diode, the variation in the temperature characteristics of the Zener diode is affected by the variation in the absolute value of the breakdown voltage Vz. If the variation in the breakdown voltage Vz of the Zener diode is large, the variation in the temperature characteristics of the Zener diode tends to be large. As a result, the temperature characteristics of the reference voltage generation part may not be stable.

The inventors of the present application have found that there are mainly two factors that cause variations in the breakdown voltage Vz in conventional Zener diodes. The first factor is that the upper anode region was formed by two ion implantations, causing tailing in the impurity concentration profile of the anode region. The second factor is that the impurity concentration profile of the lower cathode region was not uniform. These two factors greatly increase the variation in impurity concentration at the PN junction between the anode region and the cathode region, resulting in a tendency for the variation in the breakdown voltage Vz to increase.

The main purpose of the present application is to suppress the variation in the breakdown voltage Vz of the Zener diode and thereby improve the performance of the semiconductor device.

Other objects and novel features will become apparent from the description of this specification and the accompanying drawings.

The typical ones of the embodiments disclosed in the present application will be briefly described as follows.

In one embodiment, a manufacturing method of a semiconductor device includes: (a) forming a cathode region of a first conductivity type in a semiconductor substrate by ion implantation; (b) after the (a), diffusing the cathode region by a first heat treatment; and (c) after the (b), forming an anode region of a second conductivity type opposite the first conductivity type in the semiconductor substrate by ion implantation. The cathode region is formed to a deeper position from the upper surface of the semiconductor substrate than the anode region.

In one embodiment, the semiconductor device includes a cathode region of a first conductivity type, a well region of the first conductivity type, and an anode region of the second conductivity type opposite the first conductivity type, each formed in the semiconductor substrate. The impurity concentration of the cathode region is higher than the impurity concentration of the well region. In plan view, the anode region includes the cathode region. In plan view, the well region includes the anode region and the cathode region. The well region is formed to a deeper position from the upper surface of the semiconductor substrate than the anode region. The cathode region is formed to a deeper position from the upper surface of the semiconductor substrate than the anode region and the well region.

According to one embodiment, the performance of the semiconductor device can be improved.

### BRIEF DESCRIPTION OF THE DRAWINGS

FIG. 1 is a plan view showing a semiconductor device in a first embodiment.

FIG. 2 is a cross-sectional view showing the semiconductor device in the first embodiment.

FIG. 3 is a cross-sectional view showing the semiconductor device in the first embodiment.

FIG. 4 is a graph showing the impurity concentration profile of each of the anode region, the cathode region, and the well region in the first embodiment.

FIG. 5 is a cross-sectional view showing the first application example of the Zener diode in the first embodiment.

FIG. 6 is a cross-sectional view showing the second application example of the Zener diode in the first embodiment.

FIG. 7 is a cross-sectional view showing a manufacturing step of the semiconductor device in the first embodiment.

FIG. 8 is a cross-sectional view showing a manufacturing step of the semiconductor device following FIG. 7.

FIG. 9 is a cross-sectional view showing a manufacturing step of the semiconductor device following FIG. 8.

FIG. 10 is a cross-sectional view showing a manufacturing step of the semiconductor device following FIG. 9.

FIG. 11 is a cross-sectional view showing a manufacturing step of the semiconductor device following FIG. 10.

FIG. 12 is a cross-sectional view showing a manufacturing step of the semiconductor device following FIG. 11.

FIG. 13 is a plan view showing a semiconductor device in a second embodiment.

FIG. 14 is a cross-sectional view showing the semiconductor device in the second embodiment.

FIG. 15 is a graph showing the impurity concentration profile of the cathode region in a third embodiment.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, the X direction, the Y direction, and the Z direction described in the present application intersect each other and are orthogonal to each other. In this application, the Z direction is the up and down direction, depth direction, height direction, or thickness direction of a certain structure. In addition, the expression “plan view” used in the present application means that the plane formed by the X direction and the Y direction is a “plane” and the “plane” is viewed from the Z direction.

### First Embodiment

### Structure of Semiconductor Device

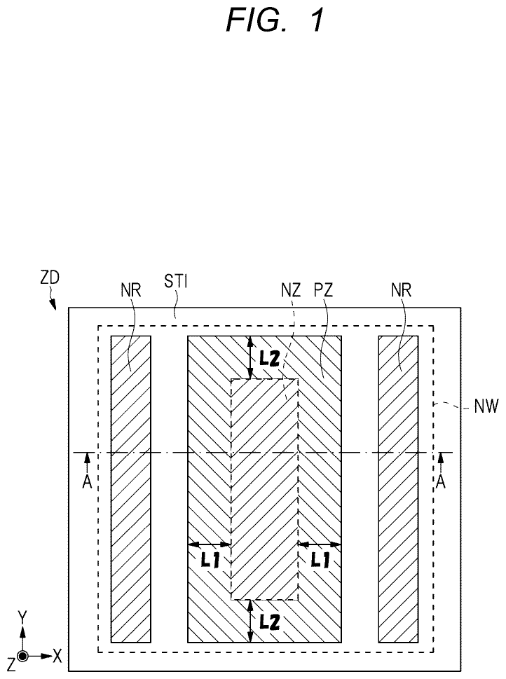

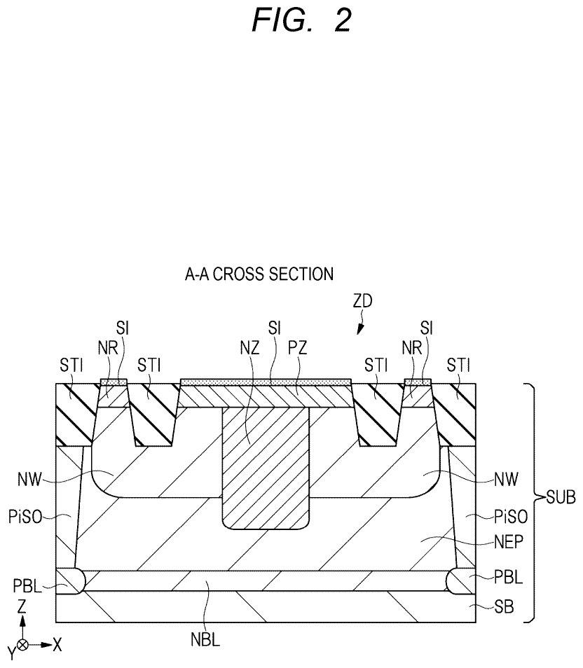

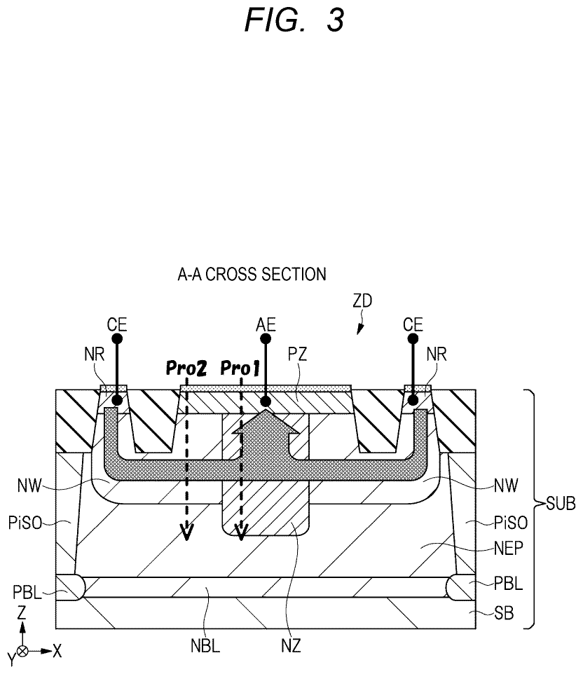

The semiconductor device (semiconductor chip) in the first embodiment will be described below with reference to FIGS. 1 to 4. FIG. 1 shows a plan view of a Zener diode ZD included in the semiconductor device. FIGS. 2 and 3 show cross-sectional views along line A-A shown in FIG. 1.

As shown in FIG. 1, the Zener diode ZD includes an n-type cathode region NZ, a p-type anode region PZ, an n-type well region NW, an n-type high concentration region NR, and an element isolation portion STI. In plan view, the anode region PZ includes the cathode region NZ. The anode region PZ and the cathode region NZ configure the main part of the Zener diode ZD.

The high concentration region NR is separated from the anode region PZ and the cathode region NZ. The element isolation portion STI is formed between the high concentration region NR and the anode region PZ and surrounds each of the high concentration region NR and the anode region PZ. In plan view, the well region NW includes the anode region PZ, the cathode region NZ, and the high concentration region NR. The high concentration region NR is electrically connected to the cathode region NZ via the well region NW and functions as a contact portion of the cathode region NZ.

As shown in FIG. 2, the Zener diode ZD is formed in a semiconductor substrate SUB. The semiconductor substrate SUB is formed of silicon. Here, the semiconductor substrate SUB is a laminated body of a support substrate SB and a semiconductor layer NEP, but is not limited to the laminated body. The support substrate SB is a laminated body of, for example, a p-type silicon substrate and a p-type silicon layer formed on the silicon substrate by an epitaxial growth method. The semiconductor layer NEP is an n-type silicon layer formed on the support substrate SB by an epitaxial growth method.

The element isolation portion STI is formed in the semiconductor substrate SUB. The element isolation portion STI includes a trench and a dielectric film. The trench is formed in the semiconductor substrate SUB and reaches a predetermined depth from the upper surface of the semiconductor substrate SUB. The dielectric film is buried in the trench. The dielectric film is, for example, a silicon oxide film.

The semiconductor substrate SUB has an n-type isolation region NBL, a p-type isolation region PBL, and a p-type isolation region PiSO. The isolation region NBL is formed at a predetermined depth in the semiconductor substrate SUB and is surrounded by the isolation region PBL. The isolation region PiSO is connected to the isolation region PBL. The Zener diode ZD is surrounded by the element isolation portion STI, the isolation region NBL, the isolation region PBL, and the isolation region PiSO, and is electrically isolated from other semiconductor elements.

The n-type cathode region NZ, the p-type anode region PZ, the n-type well region NW, and the n-type high concentration region NR are formed in the semiconductor substrate SUB. The well region NW has a higher impurity concentration than the semiconductor layer NEP. The high concentration region NR is formed in the well region NW and has a higher impurity concentration than the well region NW. The well region NW is formed to a deeper position from the upper surface of the semiconductor substrate SUB than the anode region PZ. That is, the depth of the well region NW from the upper surface of the semiconductor substrate SUB is greater than the depth of the anode region PZ from the upper surface of the semiconductor substrate SUB. The side surfaces of each of the high concentration region NR and the anode region PZ are in contact with the element isolation portion STI.

The depth of the cathode region NZ from the upper surface of the semiconductor substrate SUB is greater than the depth of the anode region PZ from the upper surface of the semiconductor substrate SUB and the depth of the well region NW from the upper surface of the semiconductor substrate SUB. The bottom of the cathode region NZ is located in the semiconductor layer NEP. The impurity concentration of the cathode region NZ is higher than the impurity concentration of the well region NW.

A silicide film SI is formed on the anode region PZ and the high concentration region NR. The silicide film SI is made of, for example, cobalt silicide, nickel silicide, or nickel platinum silicide.

FIG. 3 shows the main current path of the Zener diode ZD. As shown in FIG. 3, the semiconductor device has an anode electrode AE and a cathode electrode CE. Although not shown, the semiconductor device has an interlayer dielectric film, a plug layer, and wiring. The anode electrode AE is electrically connected to the anode region PZ, and the cathode electrode CE is electrically connected to the high concentration region NR. The interlayer dielectric film is formed on the semiconductor substrate SUB. In the interlayer dielectric film, the plug layer is formed, and on the interlayer dielectric film, wiring is formed. The cathode electrode CE and the anode electrode AE are, for example, the plug layer. The cathode electrode CE and the anode electrode AE are electrically connected to other semiconductor elements via the wiring. The plug layer is, for example, a conductive film mainly formed of a tungsten film. The wiring is, for example, a conductive film mainly formed of an aluminum alloy film or a copper film.

As indicated by the arrows in FIG. 3, the main current path of the Zener diode ZD is a path from the cathode electrode CE, through the high concentration region NR, the well region NW, the cathode region NZ, and the anode region PZ, to the anode electrode AE.

One feature of the Zener diode ZD of the first embodiment is that the cathode region NZ is formed to a deeper position from the upper surface of the semiconductor substrate SUB than the well region NW. As described above, the current flowing through the Zener diode ZD flows through the low concentration well region NW. Here, if the cathode region NZ is formed shallower than the well region NW, the proportion of the resistance of the well region NW in the current path becomes large. Since the resistance of the well region NW is higher than the resistance of the cathode region NZ, the total resistance value of the current path becomes high, and the breakdown voltage Vz of the Zener diode ZD is likely to fluctuate. By forming the high concentration cathode region NZ deeply, the total resistance value of the current path can be reduced, making it easier to suppress fluctuations in the breakdown voltage Vz.

Also, when breakdown occurs near the element isolation portion STI, electrons and holes generated at the time of breakdown may be injected into the element isolation portion STI. If breakdown occurs repeatedly, the electrons and holes accumulated in the element isolation portion STI may change the width of the depletion layer spreading at the PN junction surface in contact with the element isolation portion STI, making it difficult to stabilize the breakdown voltage.

In the first embodiment, as shown in FIG. 1, in plan view, the anode region PZ overlaps the cathode region NZ, includes the cathode region NZ, and forms a PN junction with the cathode region NZ. In other words, the outer periphery of the cathode region NZ is surrounded by the anode region PZ. In other words, in the X direction, the outer periphery of the anode region PZ is separated from the outer periphery of the cathode region NZ by a distance L1, and in the Y direction, the outer periphery of the anode region PZ is separated from the outer periphery of the cathode region NZ by a distance L2. The distances L1 and L2 are, for example, 1 μm or more and 3 μm or less.

The anode region PZ, which is close to the element isolation portion STI, does not overlap the cathode region NZ, and no impurities configuring the cathode region NZ are injected. Thus, since the anode region PZ and the cathode region NZ are arranged in this way, the impurity concentration of the anode region PZ that does not overlap the cathode region NZ is relatively higher than the impurity concentration of the anode region PZ that overlaps the cathode region NZ. Therefore, breakdown is more likely to occur at the PN junction between the anode region PZ and the cathode region NZ than at the PN junction between the anode region PZ close to the element isolation portion STI and the well region NW. Therefore, the breakdown voltage can be stabilized.

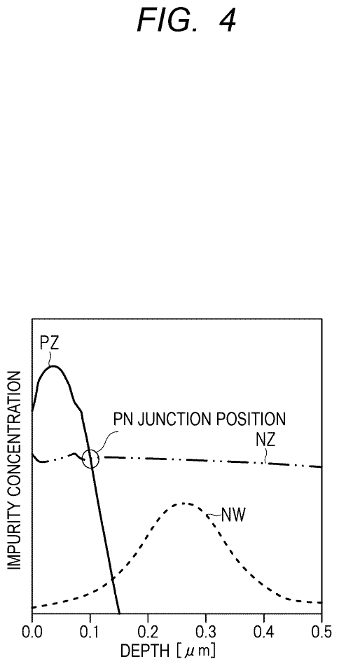

FIG. 4 shows the impurity concentration profiles of the anode region PZ and the cathode region NZ along the depth direction Pro1 shown in FIG. 3, and the impurity concentration profile of the well region NW along the depth direction Pro2.

The inventors of the present application have revealed that the factors causing variation in the breakdown voltage Vz in a conventional Zener diode are the occurrence of tailing in the impurity concentration profile of the anode region PZ and the non-uniformity of the impurity concentration profile of the cathode region NZ.

As will be described in detail in the “MANUFACTURING METHOD OF SEMICONDUCTOR DEVICE” described later, in the first embodiment, the anode region PZ is formed by a single ion implantation, thereby steepening the concentration gradient of the impurity concentration profile of the anode region PZ. In other words, no tailing occurs in the impurity concentration profile of the anode region PZ. In addition, although no heat treatment is applied to the cathode region in a conventional Zener diode, by applying a heat treatment to the cathode region NZ at a sufficient temperature and for a sufficient time, the impurity concentration profile of the cathode region NZ is made as uniform as possible.

As shown in FIG. 4, compared to the cathode region of a conventional Zener diode, the impurity concentration profile of the cathode region NZ is more uniform at a certain depth from the upper surface of the semiconductor substrate SUB to the cathode region NZ. For example, in the first embodiment, the depth of the cathode region NZ from the upper surface of the semiconductor substrate SUB is greater than 0.5 μm. Between the depth of about 0.5 μm and the upper surface of the semiconductor substrate SUB, the impurity concentration of the cathode region NZ is within the range of ±0.5×10 cm⁻³. Between the depth of 0.5 μm and the upper surface of the semiconductor substrate SUB, the impurity concentration of the cathode region NZ is, for example, within the range of 1×10¹⁸ cm⁻³ to 1×10¹⁹ cm⁻³.

In other words, the concentration gradient of the impurity concentration profile of the cathode region NZ is smaller than the concentration gradient of the impurity concentration profile of the well region NW. Also, the half-width of the impurity concentration profile of the anode region PZ and the half-width of the impurity concentration profile of the well region NW are smaller than the half-width of the impurity concentration profile of the cathode region NZ.

Thus, compared to the cathode region of a conventional Zener diode, since the impurity concentration profile of the cathode region NZ is more uniform, the impurity concentration profiles of the cathode region NZ and the anode region PZ intersect at an angle close to vertical. For example, the impurity concentration profiles of the cathode region NZ and the anode region PZ intersect at an angle of 70 degrees or more and 90 degrees or less. Therefore, the variation in impurity concentration at the PN junction is reduced, and the variation in the breakdown voltage Vz can be suppressed, which can improve the performance of the semiconductor device.

### First Application Example of Zener Diode ZD

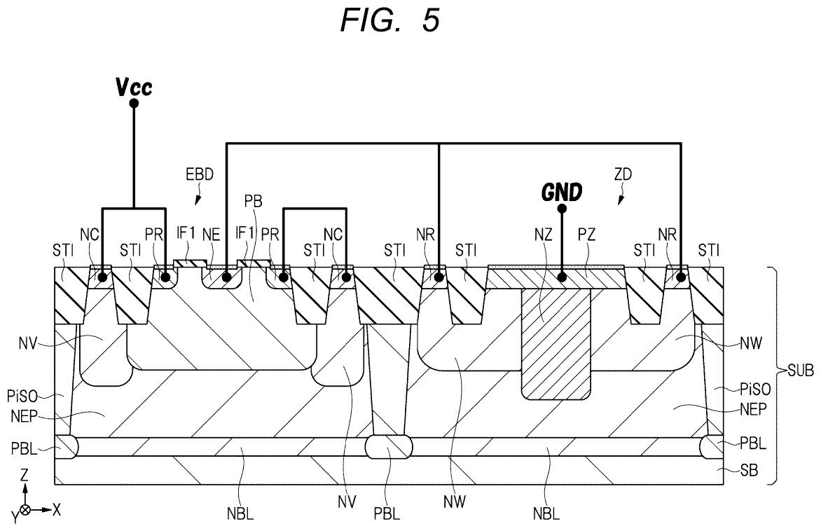

FIG. 5 is a cross-sectional view of a reference voltage generation part of a DESAT detection circuit to which the Zener diode ZD and an emitter base diode EBD connected in the forward direction are applied. The emitter base diode EBD is formed in a region different from the Zener diode ZD in the semiconductor device.

Hereinafter, the structure of the emitter base diode EBD will be described. The emitter base diode EBD has an n-type well region NV, a p-type base region PB, an n-type collector region NC, an n-type emitter region NE, and a p-type high concentration region PR. As shown in FIG. 5, the well region NV and the base region PB are formed in the semiconductor substrate SUB. The collector region NC is formed in the well region NV. The collector region NC has a higher impurity concentration than the well region NV. The emitter region NE and the high concentration region PR are formed in the base region PB. The high concentration region PR has a higher impurity concentration than the base region PB.

On the semiconductor substrate SUB, a dielectric film IF1 is selectively formed to expose the collector region NC, the emitter region NE, and the high concentration region PR. The silicide film SI is formed on the upper surface of the semiconductor substrate SUB exposed from the dielectric film IF1 and the element isolation portion STI. That is, the silicide film SI is formed on the collector region NC, the emitter region NE, and the high concentration region PR.

The well region NV and the collector region NC configure the collector of the bipolar transistor, the base region PB and the high concentration region PR configure the base of the bipolar transistor, and the emitter region NE configures the emitter of the bipolar transistor. The emitter base diode EBD is formed by electrically short-circuiting the collector and the base.

By electrically connecting the anode region PZ to the reference voltage GND, electrically connecting the high concentration region NR (cathode region NZ) to the emitter region NE, and electrically connecting the collector region NC and the high concentration region PR (base region PB) to the power supply voltage Vcc, the reference voltage generation part of the DESAT detection circuit is formed.

In the Zener diode ZD of the first embodiment, the variation of the breakdown voltage Vz of the Zener diode ZD is suppressed. Therefore, it is possible to realize the DESAT detection circuit that can prevent malfunction due to noise by narrowing the standard width of the DESAT detection voltage. Also, since the variation of the breakdown voltage Vz of the Zener diode ZD is suppressed, the variation of the temperature characteristics of the Zener diode ZD can also be suppressed, and the temperature characteristics of the reference voltage generation part can be stabilized.

### Second Application Example of Zener Diode ZD

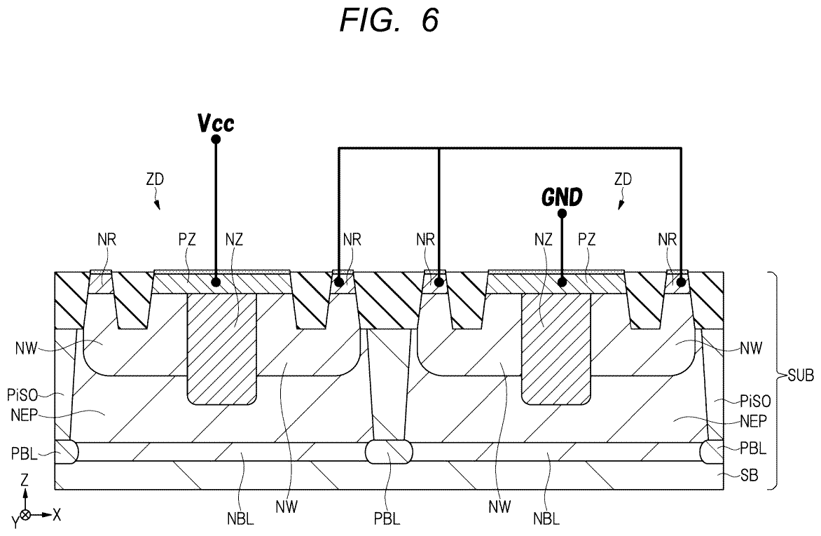

FIG. 6 is a cross-sectional view of the reference voltage generation part of the DESAT detection circuit, which applies two Zener diodes ZD connected in the forward direction. The two Zener diodes ZD are formed in different regions in the semiconductor device.

By electrically connecting one anode region PZ to the reference voltage GND, electrically connecting one high concentration region NR (cathode region NZ) to the other high concentration region NR (cathode region NZ), and electrically connecting the other anode region PZ to the power supply voltage Vcc, the reference voltage generation part of the DESAT detection circuit is formed.

In the second application example as well, since the variation of the breakdown voltage Vz of the two Zener diodes ZD is suppressed, it is possible to realize the DESAT detection circuit that can prevent malfunction due to noise by narrowing the standard width of the DESAT detection voltage.

### Manufacturing Method of Semiconductor Device

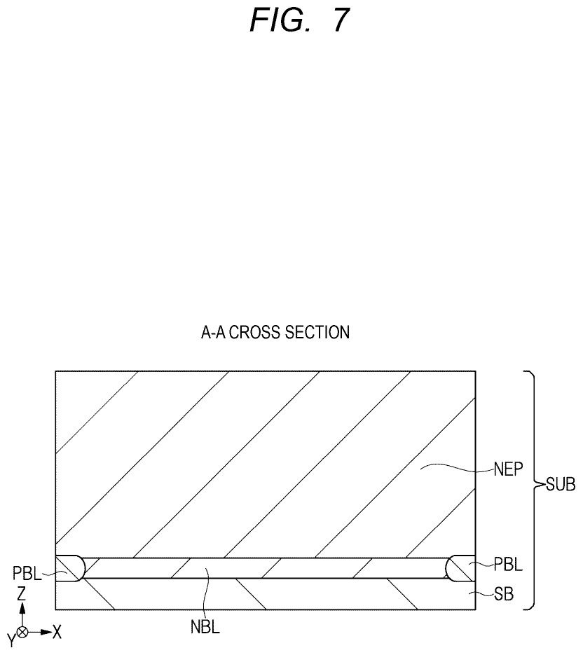

Hereinafter, each manufacturing step included in the manufacturing method of the semiconductor device in the first embodiment will be described using FIGS. 7 to 12.

First, as shown in FIG. 7, the semiconductor substrate SUB made of silicon is prepared. As described above, the semiconductor substrate SUB is a laminated body of the support substrate SB and the semiconductor layer NEP. By photolithography and ion implantation, the isolation region NBL and the isolation region PBL are selectively formed in the support substrate SB. The isolation region NBL and the isolation region PBL are arranged at a predetermined depth from the upper surface of the semiconductor substrate SUB. On the support substrate SB, the semiconductor layer NEP is formed by introducing n-type impurities using the epitaxial growth method. In this way, the semiconductor substrate SUB is prepared.

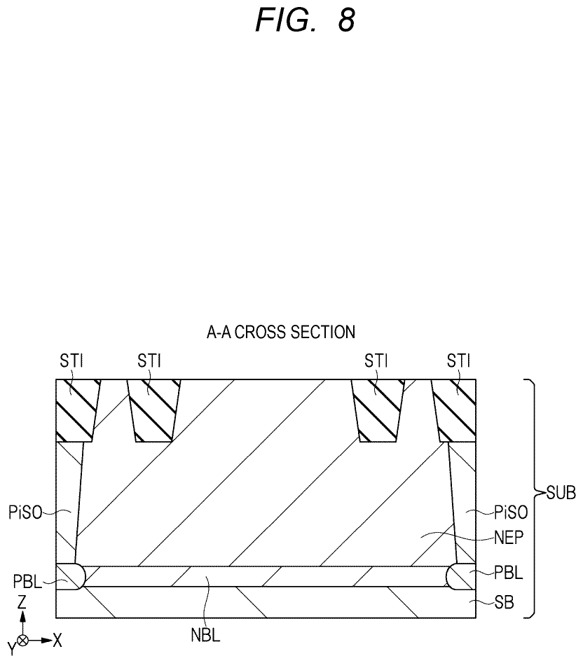

As shown in FIG. 8, the element isolation portion STI and the isolation region PiSO are formed in the semiconductor substrate SUB. First, using photolithography techniques and ion implantation, the p-type isolation region PiSO is selectively formed in the semiconductor substrate SUB.

Next, using photolithography techniques and etching treatment, a trench is formed in the semiconductor substrate SUB. The trench is formed to overlap the isolation region PiSO. Next, for example, by the CVD method, a dielectric film is formed on the upper surface of the semiconductor substrate SUB to fill the trench. The dielectric film is, for example, a silicon oxide film or a silicon nitride film. Next, using methods such as CMP (Chemical Mechanical Polishing), the dielectric film formed outside the trench is removed. Thus, the element isolation portion STI, which includes the trench and the dielectric film, is formed in the semiconductor substrate SUB.

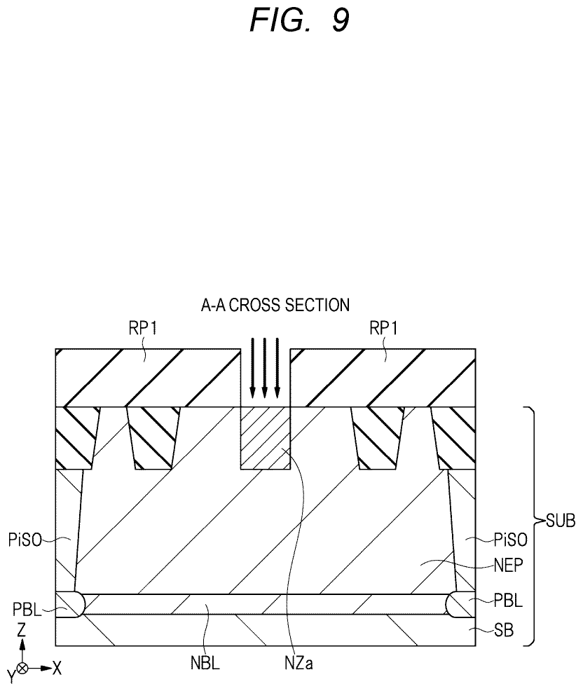

As shown in FIG. 9, an n-type cathode region NZa is formed in the semiconductor substrate SUB. First, a resist pattern RP1 is formed on the upper surface of the semiconductor substrate SUB. Next, by performing ion implantation using the resist pattern RP1 as a mask, the cathode region NZa is formed in the semiconductor substrate SUB. Next, the resist pattern RP1 is removed by ashing.

The ion implantation of the cathode region NZa is performed using phosphorus (P) as an impurity, for example, with an implant energy of 70 keV or more and 90 keV or less, and a dose amount of 1.5×10¹⁴ cm⁻² or more and 6.0×10¹⁴ cm⁻² or less.

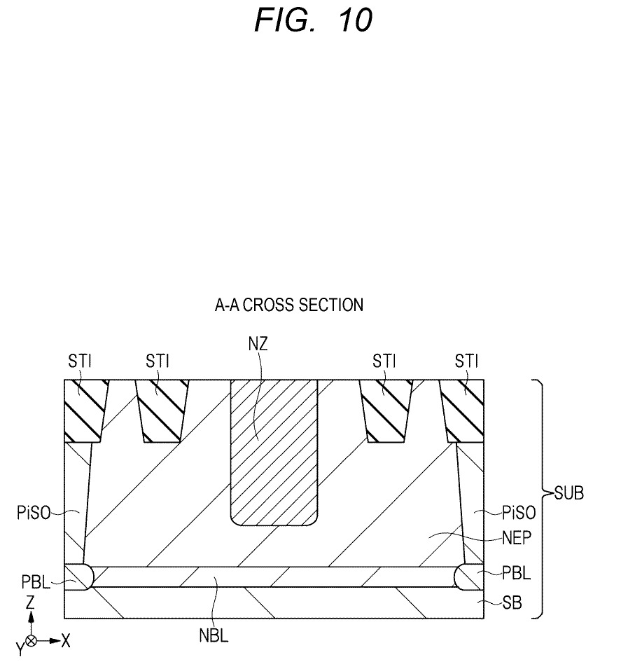

As shown in FIG. 10, the cathode region NZa is diffused by heat treatment to form the cathode region NZ. The heat treatment is performed in a nitrogen atmosphere, for example, at 1100 degrees Celsius or more for 60 minutes or more. After the heat treatment, as shown in FIG. 4, compared to the cathode region of a conventional Zener diode, the impurity concentration profile of the cathode region NZ becomes more uniform at a predetermined depth from the upper surface of the semiconductor substrate SUB.

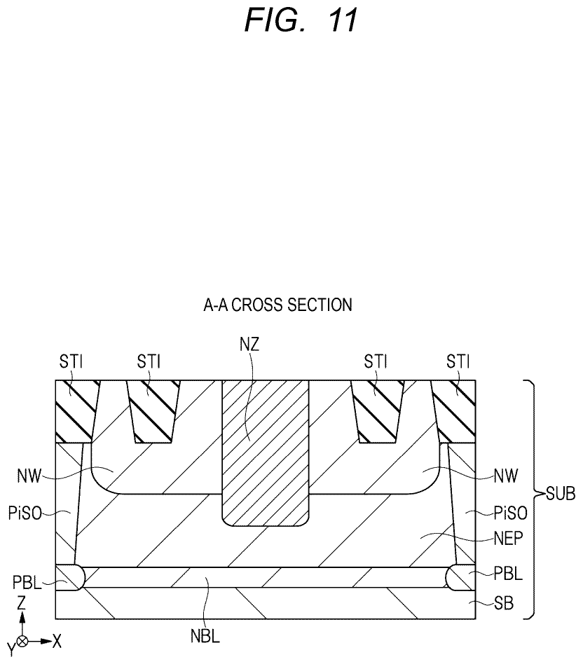

As shown in FIG. 11, the n-type well region NW is selectively formed in the semiconductor substrate SUB using photolithography techniques and ion implantation.

The ion implantation of the well region NW is performed using phosphorus (P) as an impurity, for example, with an implant energy of 40 keV or more and 60 keV or less, and a dose amount of 1.0×10¹³ cm⁻² or more and 5.0×10¹³ cm⁻² or less.

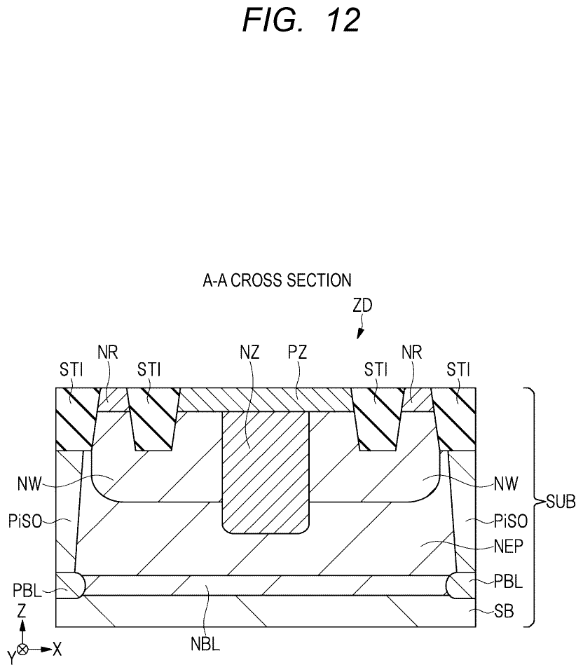

As shown in FIG. 12, the p-type anode region PZ and the n-type high concentration region NR are selectively formed in the semiconductor substrate SUB using photolithography techniques and ion implantation.

The ion implantation of the anode region PZ is performed using boron difluoride (BF2) as an impurity, for example, with an implant energy of 50 keV or more and 70 keV or less, and a dose amount of 1.0×10¹⁵ cm⁻² or more and 5.0×10¹⁵cm⁻² or less.

The ion implantation of the high concentration region NR is performed using arsenic (As) as an impurity, for example, with an implant energy of 30 keV or more and 50 keV or less, and a dose amount of 1.0×10¹⁵ cm⁻² or more and 5.0×10¹⁵ cm⁻² or less.

Next, heat treatment is performed to activate the impurities contained in the well region NW, the anode region PZ, and the high concentration region NR. The heat treatment is performed in a nitrogen atmosphere, for example, at 900 degrees Celsius or more and 950 degrees Celsius or less, for 1 second or more and 10 seconds or less. The impurity concentration profiles of the well region NW and the anode region PZ after the heat treatment are shown in FIG. 4. Note that this heat treatment does not significantly change the impurity concentration profile of the cathode region NZ. Furthermore, since the ion implantation of the anode region PZ is performed by a single ion implantation, the concentration gradient of the impurity concentration profile of the anode region PZ becomes steep.

By the above manufacturing steps, the Zener diode ZD is formed in the semiconductor substrate SUB.

Subsequently, the structure shown in FIG. 2 is obtained through the following manufacturing steps. First, the dielectric film IF1 made of, for example, a silicon oxide film is formed on the upper surface of the semiconductor substrate SUB by, for example, a CVD method. (For the dielectric film IF1, refer to the emitter base diode EBD in FIG. 5.) Then, the dielectric film IF1 is selectively patterned by photolithography technique and etching treatment.

Next, using existing salicide technique, the silicide film SI is formed in the region exposed from the dielectric film IF1 and the element isolation portion STI. That is, in the Zener diode ZD, the silicide film SI is formed on the anode region PZ and the high concentration region NR.

### Second Embodiment

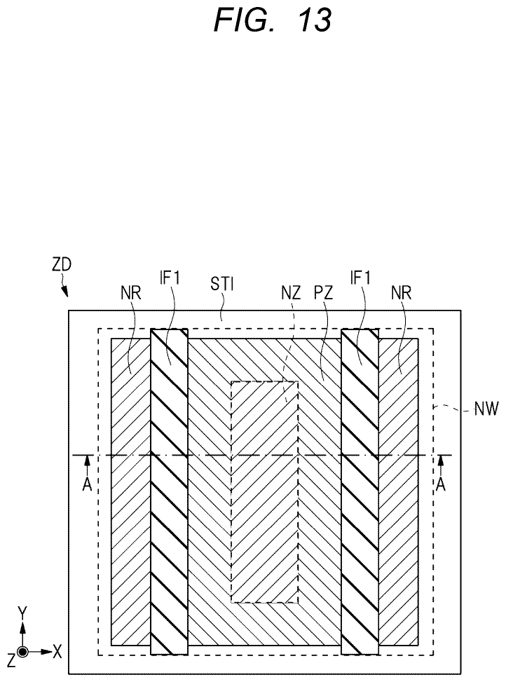

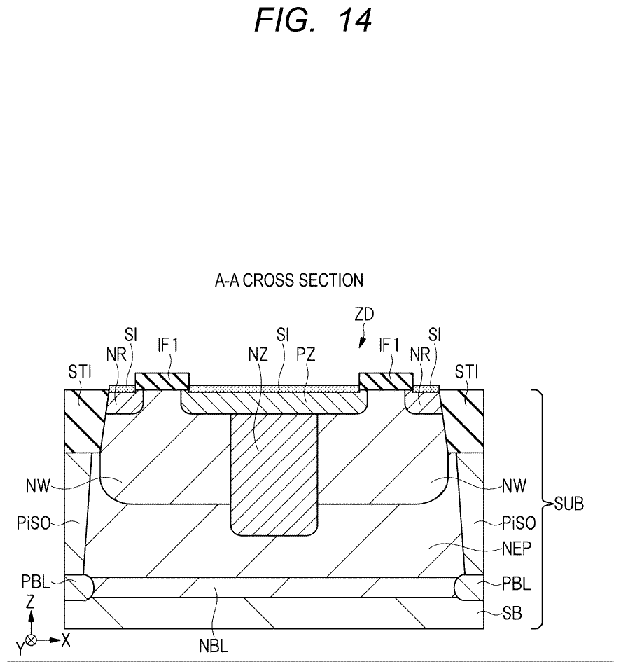

Hereinafter, a semiconductor device in the second embodiment will be described using FIGS. 13 and 14. Note that, in the following description, differences from the first embodiment will be mainly described, and the description of overlapping points with the first embodiment will be omitted.

In the first embodiment, the element isolation portion STI is formed between the high concentration region NR and the anode region PZ.

In the second embodiment, as shown in FIGS. 13 and 14, the element isolation portion STI is not formed between the high concentration region NR and the anode region PZ. The high concentration region NR and the anode region PZ are separated from each other, and the side surfaces of the high concentration region NR and the anode region PZ are in contact with the well region NW.

As described above, if breakdown occurs repeatedly near the element isolation portion STI, electrons and holes generated at the time of breakdown accumulate in the element isolation portion STI, making it difficult to stabilize the breakdown voltage. Therefore, in the second embodiment, by not forming the element isolation portion STI where electrons and holes can be injected near the PN junction surface between the anode region PZ and the well region NW, the breakdown voltage can be further stabilized.

Also, since the current does not bypass the element isolation portion STI, the current path of the second embodiment becomes shorter than the current path of the first embodiment. The resistance component of the current path of the Zener diode ZD passing through the well region NW is reduced. Therefore, the total resistance value of the current path can be reduced, and the fluctuation of the breakdown voltage Vz can be further suppressed.

However, by not forming the element isolation portion STI, when the silicide film SI is formed, the silicide film SI is also formed on the well region NW located between the high concentration region NR and the anode region PZ. Then, the anode electrode AE and the cathode electrode CE are connected via the silicide film SI. (See FIG. 3.)

Therefore, the dielectric film IF1 is patterned so that the dielectric film IF1 remains on the well region NW located between the high concentration region NR and the anode region PZ. This can suppress the formation of the silicide film SI between the high concentration region NR and the anode region PZ, and selectively form the silicide film SI on the high concentration region NR and the anode region PZ.

### Third Embodiment

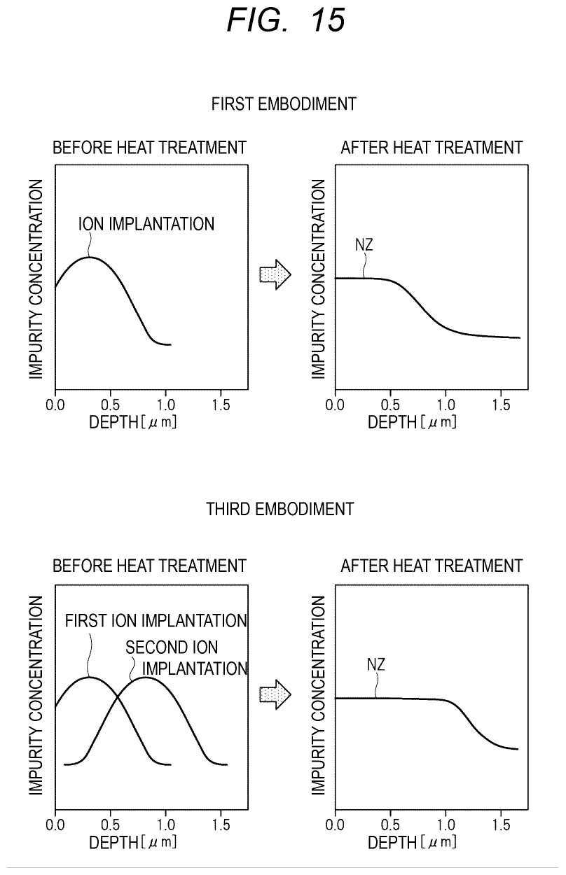

Hereinafter, a semiconductor device in the third embodiment will be described using FIG. 15. Note that, in the following description, differences from the first embodiment will be mainly described, and the description of overlapping points with the first embodiment will be omitted.

In the first embodiment, in the manufacturing step of FIG. 9, the ion implantation of the cathode region NZa is performed by a single ion implantation.

In the third embodiment, as shown in FIG. 15, the ion implantation of the cathode region NZa is performed by multiple ion implantations using different implant energies. Here, an example of forming the cathode region NZa by two ion implantations is illustrated, but the number of ion implantations may be three or more. The conditions of impurities and dose amounts in multiple ion implantations are the same as the conditions of the manufacturing step in FIG. 9.

By performing multiple ion implantations, it becomes possible to form the cathode region NZa to a deeper position than the cathode region NZa in the first embodiment. Also, even when multiple ion implantations are performed, by performing the heat treatment in FIG. 10, the impurity concentration profile of the cathode region NZ becomes more uniform at a predetermined depth from the upper surface of the semiconductor substrate SUB, compared to the cathode region of the conventional Zener diode. In the third embodiment, the depth of the cathode region NZ from the upper surface of the semiconductor substrate SUB is greater than 1.0 μm, and the impurity concentration of the cathode region NZ is within the range of ±0.5×10 cm⁻³ between a depth of 1.0 μm and the upper surface of the semiconductor substrate SUB. For example, the impurity concentration of the cathode region NZ is within the range of 1×10¹⁸ cm⁻³ to 1×10¹⁹ cm⁻³.

Thus, compared to the first embodiment, the technique of the third embodiment can form the cathode region NZ with a more uniform impurity concentration profile to a deeper position. The technique described in the third embodiment can be combined with the technique of the second embodiment.

Although the present invention has been described in detail based on the above-described embodiments, the present invention is not limited to the above-described embodiments, and can be variously modified without departing from the gist thereof.

What is claimed is:

1. A method of manufacturing a semiconductor device, the method comprising:
(a) forming a first cathode region of a first conductivity type in a semiconductor substrate by a first ion implantation;
(b) after the (a), diffusing the first cathode region by a first heat treatment to form a second cathode region; and
(c) after the (b), forming an anode region of a second conductivity type opposite the first conductivity type in the semiconductor substrate by a second ion implantation,
wherein a depth of the second cathode region from an upper surface of the semiconductor substrate is greater than a depth of the anode region from the upper surface of the semiconductor substrate.

2. The method according to claim 1,
wherein in plan view, the anode region includes the second cathode region.

3. The method according to claim 2,
wherein the anode region forms a PN junction with the second cathode region.

4. The method according to claim 1,
wherein in the (c), the second ion implantation is performed by single ion implantation.

5. The method according to claim 1,
wherein the first heat treatment is performed at a temperature of 1100 degrees Celsius or higher and for 60 minutes or more.

6. The method according to claim 5,
wherein the depth of the second cathode region is greater than 0.5 μm, and
wherein between the upper surface of the semiconductor substrate and a depth of 0.5 μm, an impurity concentration of the second cathode region is within a range of ±0.5×10 cm⁻³.

7. The method according to claim 1,
wherein in the (a), the first ion implantation is performed by multiple ion implantations using different implant energies.

8. The method according to claim 1, comprising:
(d) between the (b) and the (c), forming a well region of the first conductivity type in the semiconductor substrate by a third ion implantation,
wherein an impurity concentration of the second cathode region is higher than an impurity concentration of the well region,
wherein in plan view, the well region includes the anode region and the second cathode region,
wherein a depth of the well region from the upper surface of the semiconductor substrate is greater than the depth of the anode region,
wherein the depth of the second cathode region is greater than the depth of the well region.

9. The method according to claim 8,
wherein a concentration gradient of a concentration profile of the second cathode region is smaller than a concentration gradient of a concentration profile of the well region.

10. The method according to claim 8,
wherein a half-width of a concentration profile of the anode region and a half-width of a concentration profile of the well region are smaller than a half-width of a concentration profile of the second cathode region.

11. The method according to claim 8, comprising:
(e) after the (d), forming a high concentration region of the first conductivity type in the well region by a fourth ion implantation,
wherein an impurity concentration of the high concentration region is higher than the impurity concentration of the well region, and
wherein the high concentration region is separated from the anode region and the second cathode region.

12. The method according to claim 11, comprising:
(f) before the (a), forming a trench in the semiconductor substrate; and
(g) between the (f) and the (a), filling the trench with a first dielectric film to form an element isolation portion including the trench and the first dielectric film,
wherein the element isolation portion is formed between the high concentration region and the anode region, and
wherein a side surface of the anode region is in contact with the element isolation portion.

13. The method according to claim 11,
wherein a side surface of the anode region is in contact with the well region.

14. A semiconductor device comprising:
a cathode region of a first conductivity type formed in a semiconductor substrate;
a well region of the first conductivity type formed in the semiconductor substrate; and
an anode region of a second conductivity type opposite the first conductivity type formed in the semiconductor substrate,
wherein an impurity concentration of the cathode region is higher than an impurity concentration of the well region,
wherein in plan view, the anode region includes the cathode region,
wherein in plan view, the well region includes the anode region and the cathode region,
wherein a depth of the well region from an upper surface of the semiconductor substrate is greater than a depth of the anode region from the upper surface of the semiconductor substrate, and
wherein a depth of the cathode region from the upper surface of the semiconductor substrate is greater than the depth of the anode region and the depth of the well region.

15. The semiconductor device according to claim 14,
wherein the depth of the cathode region is greater than 0.5 μm, and
wherein between the upper surface of the semiconductor substrate and a depth of 0.5 μm, the impurity concentration of the second cathode region is within a range of ±0.5×10 cm⁻³.

16. The semiconductor device according to claim 14,
wherein a concentration gradient of a concentration profile of the cathode region is smaller than a concentration gradient of a concentration profile of the well region.

17. The semiconductor device according to claim 14,
wherein a half-width of a concentration profile of the anode region and a half-width of a concentration profile of the well region are smaller than a half-width of a concentration profile of the cathode region.

18. The semiconductor device according to claim 14, comprising:
a high concentration region of the first conductivity type formed in the well region,
wherein an impurity concentration of the high concentration region is higher than the impurity concentration of the well region, and
wherein the high concentration region is separated from the anode region and the cathode region.

19. The semiconductor device according to claim 18, comprising:
an element isolation region comprising:
a trench formed in the semiconductor substrate; and
a first dielectric film buried in the trench,
wherein the element isolation portion is formed between the high concentration region and the anode region, and
wherein a side surface of the anode region is in contact with the element isolation portion.

20. The semiconductor device according to claim 18,
wherein a side surface of the anode region is in contact with the well region.
